(19) United States
(12) Patent Application Publication
(10) Pub. No.: US 2004/0183575 A1
(43) Pub. Date: Sep. 23, 2004

(54) Sinusoidal drive waveforms for digital or mixed-mode integrated circuits

(76) Inventor: Donald A. Symes, Tucson, AZ (US)

Correspondence Address: NATIONAL IP RIGHTS CENTER, LLC, SCOTT J. FIELDS, ESQ., 550 TOWNSHIP LINE ROAD, SUITE 400, BLUE BELL, PA, 19422, US

(21) Appl. No.: 10/392,360

(22) Filed: Mar. 19, 2003

(51) Int. Cl. H03B 1/00

(52) U.S. Cl. 327/129

(57) ABSTRACT

A signaling circuit using sinusoidal driven waveforms is disclosed. The circuit comprises sinusoidal circuit creation means comprising at least one voltage source for driving a pair of offset sinusoidal waveform into a driver circuit; said driver circuit comprising at least two transistors to hold either a Hi or Lo state and a pair of gated buffers to route either phase of the sinusoid pair to an output pin; and logic circuit means to select between either a plurality of hold states (Hi, Lo, or Z (neither)) or the sinusoid phase, thereby generating a required transition during a preset transition period.

### FIELD OF THE INVENTION

The present invention relates to integrated circuit microelectronics. In particular, the invention is directed to logic signal drivers used to communicate with other integrated circuits in an electronic device or system, as well as which communicate along heavily loaded signal paths within a given integrated circuit.

### BACKGROUND AND SUMMARY OF THE INVENTION

The normal practice in designing a digital I/O driver is to use large transistors which operate at relatively high currents in an attempt to force the signal waveform to approximate a square wave or step function. Generating these sharp-edged waveforms requires injecting substantial energies at harmonic frequencies that are several times the fundamental (highest desired square wave frequency).

These high signal currents and extra-high-frequency signal energy content combine with basic circuit physics to tax system design in several ways. First High switching currents at high slew rates, combine with the di/dt characteristics of the inherent inductance of the current path from the power supply rails, through the IC package and die power distribution networks, to the output driver and on through the output pin, to impose localized fluctuations in power supply voltages on the IC die.

These supply fluctuations, which are referred to as a ‘ground bounce’ can be a particularly troublesome cause of inconsistent circuit operation because they can disturb reference levels and cause signals to appear to re-cross threshold levels. A particularly bad ground bounce event can trigger a destructive latch-up condition in a CMOS device. Mitigating these issues complicates the power supply decoupling strategy and tends to increase its complexity and cost.

The electrical length of a signal path is determined as much by the edge rate of the signal as by the physical distance traced out by the path: a signal having a time-of-flight from source to destination greater than that signal's rise time (edge rate) is being launched on a transmission line and is subject to perturbation by reflections at each discontinuity in the path's impedance—every change of medium, material or distance from a reference plane. Signal traces as short as 1.0 inch (2.54 cm) are becoming significantly long, electrically, and are starting to require the engineering attention once only given signal traces tens of inches long—impedance control and signal termination strategies must be considered for nearly every trace in a system.

Electromagnetic emissions are becoming more problematic as regulatory agencies are pushing for lower and lower limits at the higher frequencies just as the energies generated at those frequencies are being driven higher in an effort to override circuit physics.

The present invention addresses all of these problems by abandoning the sharp-edged trapezoidal driver waveform in favor of a sinusoidal-or sigmoidal-derived waveform. In a system using sinusoidal drivers, the fundamental frequency is the highest frequency in the system carrying any significant energy and the steps taken to abate emissions at the fundamental can be expected to substantially abate emissions at the fundamental's sub-harmonics. Further, because switching currents are lower, and the di/dt figure is further lowered by the lack of harmonic content, inductive ground bounce effects are greatly reduced—and thereby, so are the demands on the decoupling network.

There have been a number of patents in the prior art directed to sinusoidal wave generation. None disclose the present invention. U.S. Pat. No. 5,485,153 for example, discloses a sinusoidal wave generation apparatus comprising a pulse generator for generating a pulse signal of a precise frequency in response to a clock signal from an oscillator, a frequency divider for dividing the precise frequency of the pulse signal from the pulse generator by a desired ratio to output a desired frequency of pulse signal, an up/down counter for alternately up-counting and down-counting the frequency-divided pulse signal from the frequency divider and outputting up/down-counted values corresponding to digital triangular wave data, a digital/analog converter for converting the digital triangular wave data of the up/down-counted values from the up/down counter into an analog triangular wave signal, a low pass filter for filtering a harmonic component of the analog triangular wave signal from the digital/analog converter to output a sinusoidal wave signal, a comparison circuit for comparing the up/down-counted values from the up/down counter with predetermined upper and lower reference values, respectively, and outputting pulse signals in accordance with the compared results, and a latch unit for changing the up-counting operation of the up/down counter to the down-counting operation thereof and vice versa in response to the pulse signals from the comparison circuit.

U.S. Pat. No. 6,518,802 discloses a numerically controlled oscillator that generates an accurate digital representation of a repeating waveform such as a sinusoidal wave. Based on the desired output frequency, multiple samples are calculated from multiple cycles of the repeating waveform. As samples are taken, they are stored in a memory location until a sufficient number of samples are accumulated. After the samples are accumulated, they are output in a specified order, which generates an accurate digital representation of a sinusoidal wave at the desired output frequency.

U.S. Pat. No. 5,819,099 discloses a digital data signal voltage converter for converting a first digital data signal that is asserted at a first pair of voltage levels that are considered the inverse of one another, the two voltage levels being a first low voltage level and a first high voltage level, to a second digital data signal that is asserted at a second pair of voltage levels that are considered the inverse of one another, the second pair of voltage levels being a second low voltage level and a second high voltage level, the second high voltage level being higher than the first high voltage level. The voltage converter includes an active pull-up transistor and an active pull-down transistor, along with circuitry for controlling the second high voltage level. Three-state control may be provided to allow use as an input/output terminal.

The present invention seeks to improve over the prior art and solve the problems experienced by the prior art by abandoning the sharp-edged trapezoidal driver waveform in favor of a sinusoidal-or sigmoidal-derived waveform. In a system using sinusoidal drivers, the fundamental frequency is the highest frequency in the system carrying any significant energy and the steps taken to abate emissions at the fundamental can be expected to substantially abate emissions at the fundamental's sub-harmonics.

### SUMMARY OF THE INVENTION

In accordance with the present invention, a signaling circuit using sinusoidal driven waveforms comprising: circuit means for driving a pair of sinusoidal waveforms into a driver circuit; a driver circuit to route either phase of the sinusoid pair to an output pin; and logic means for selecting between the hold states (Hi, Lo, or Z (neither)) or the sinusoid phase making the required transition during a given transition time.

In a further embodiment, the present invention comprises a signaling circuit using sinusoidal driven waveforms comprising: sinusoidal circuit creation means comprising at least one voltage source for driving a pair of offset sinusoidal waveform into a driver circuit; said driver circuit comprising at least two transistors to hold either a Hi or Lo state and a pair of gated buffers to route either phase of the sinusoid pair to an output pin; and logic circuit means to select between either a plurality of hold states (Hi, Lo, or Z (neither)) or the sinusoid phase, thereby generating a required transition during a preset transition period.

In still a further embodiment, the present invention comprises a signaling circuit using sinusoidal driven waveforms comprising: sinusoidal circuit creation means comprising at least one voltage source for driving a pair of offset sinusoidal waveform into a driver circuit; said driver circuit comprising at least two transistors to hold either a Hi or Lo state and a pair of gated buffers, controlled by a NOR circuit, to route either phase of the sinusoid pair to an isolated output pin; and logic circuit means to select between either a plurality of hold states or the sinusoid phase, thereby generating a required transition during a preset transition period.

### DESCRIPTION OF THE FIGURES

FIG. 1 is a block diagram of the present invention.

FIG. 2 illustrates the sinusoidal function of the present invention.

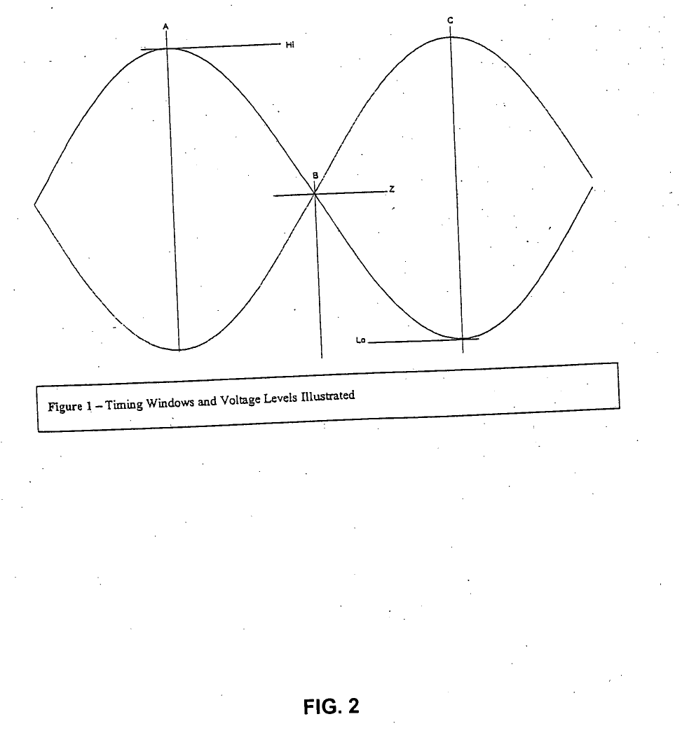

FIG. 3 is a sinusoidal edge driver in accordance with the present invention.

FIG. 4 is an alternative embodiment of the present invention.

FIG. 5 is a network of transmission lines connecting two sinusoidal edge drivers, four loads and two termination networks.

FIG. 6 illustrates a drive waveform plot.

FIG. 7 illustrates a second drive waveform plot.

### DETAILED DESCRIPTION OF THE INVENTION

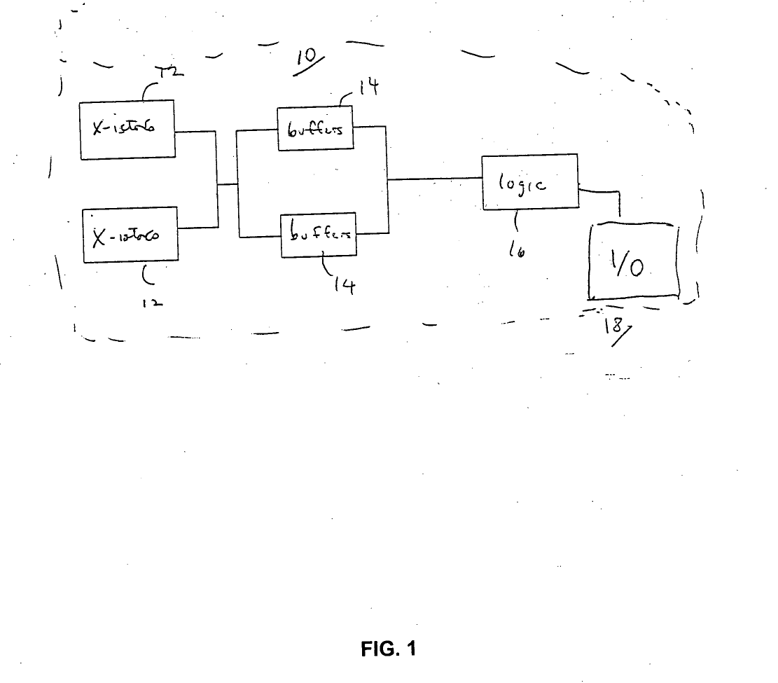

The present invention is described with response to the enclosed Figures wherein the same numbers are utilized where applicable. Referring first to FIG. 1, the sinusoidal edge driver of the present invention is shown. The driver requires that a differential pair of sinusoids be available at each output driver so that either a low-to-high or high-to-low transition is available during any transition window. Referring to FIG. 1, six transitions are defined, with three possible valid transition windows. These transitions are: A->C (H->L, L->H), A->B (H->Z, L->Z) and B>C (Z->H, Z->L).

The pair of sinusoids may be generated by a central system resource that produces a plurality of differential pairs of sinusoids one for each agent using sinusoidal edge drivers. Alternatively, the central system resource may produce single-ended sinusoids. The agents may use PLL or DLL techniques to generate the opposite phase of sinusoid pair. In small, low-cost, highly integrated systems, that system resource may be integrated into any convenient device. Referring to FIG. 1, the edge driver (10) in a most preferred embodiment comprises at least two transistors (12) to hold either a Hi or Lo state, a pair of gated buffers (14) to route either phase of the sinusoid pair to the output pin, and logic (16) required to select between the hold states (Hi, Lo, or Z (neither)) or the sinusoid phase making the required transition during a given transition time. This driver (10) may be integrated with other circuits to form an I/O cell (18), which will, in fact, be the most common embodiment. The sinusoidal Edge Drivers (10) in a preferred embodiment, may be implemented in any saturating logic family, i.e., bipolar TTL, CMOS, NMOS, BiCMOS, etc., but are probably not suited for the non-saturating families like ECL/pECL.

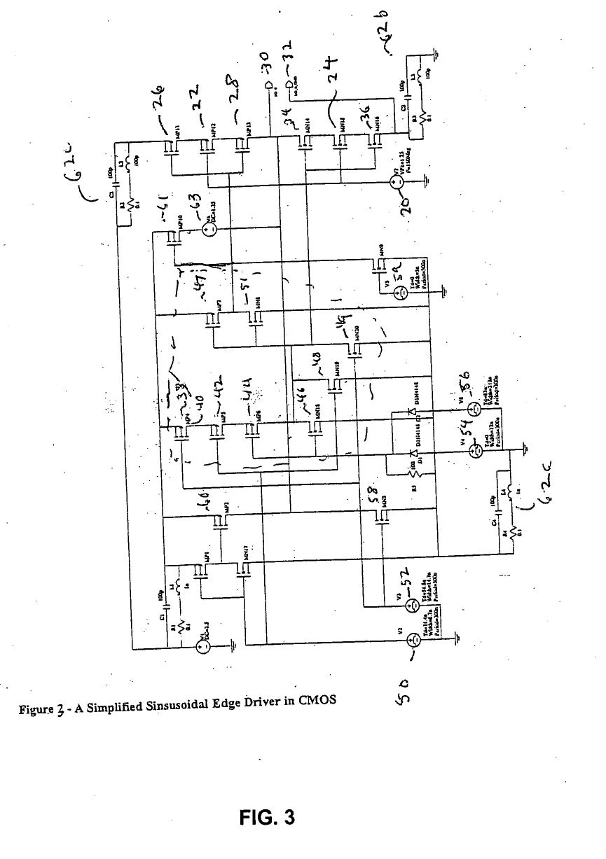

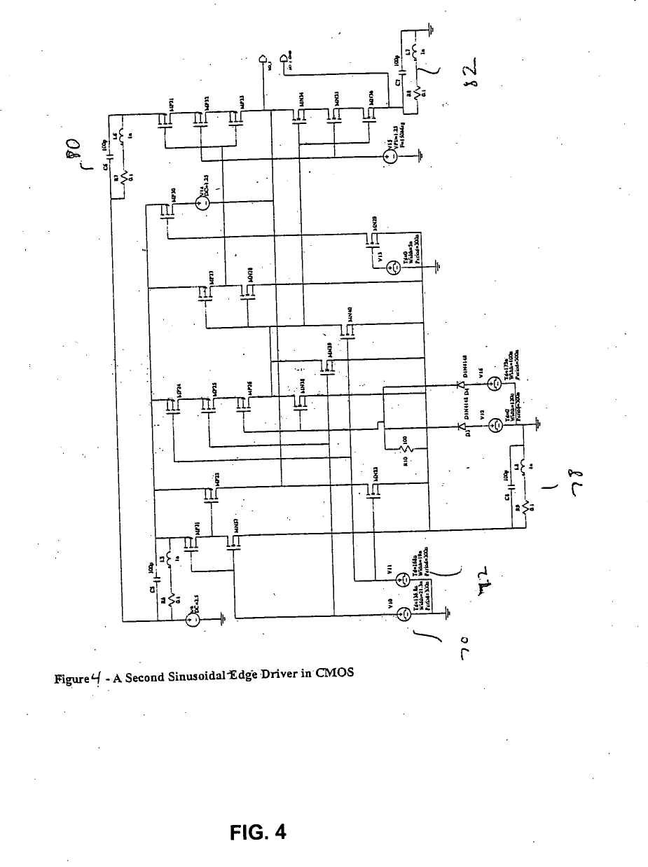

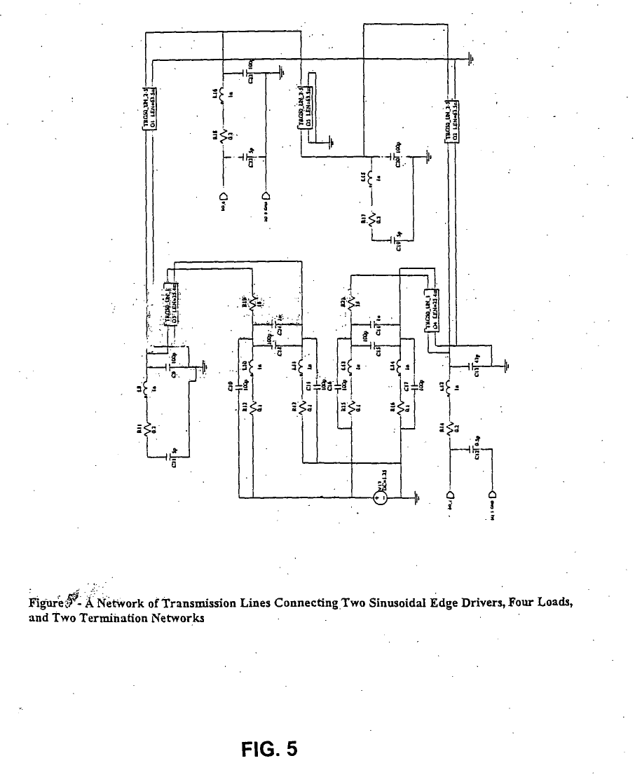

FIGS. 3, 4, and 5 implement a simplified, single-phase version of a sinusoidal edge driver in accordance with the present invention suitable for demonstration of the technology through circuit simulation using spice or similar circuit analysis software. FIGS. 3 and 4 disclose a single phase of the output driver and sufficient timing and control elements to demonstrate the operation of a bidirectional signal trace, which is implemented in FIG. 5.

As shown in FIG. 3, V7 (20) is the source of the single phase sinusoidal waveform, which activates output driver transistors MP12 (22) and MN15 (24). Transistors MP11 (26) and MP13 (28) isolate transistor MP12 (22) from, respectively, the Vdd rail (30) and the output pin (32). Transistors MN14 (34) and MN16 (36) likewise isolate MN15 (24) from the Vss rail and the output pin (32). The four devices transistors (26) (28) (34) (36) act effectively to gate the sinusoid's ability to drive or otherwise affect the output pin and the signal trace it drives.

These gate transistors are controlled by the NOR gate (38) hashed lines formed by MP4 (40), MP5 (42) and MP6 (44), and MN18 (46), MN19 (48) and MN20 (49), with MP7 (47) and MN8 (51) performing the logic inversion required to operate the high-side gate (MP11 (26) and 13 (28) in concert with the low-side gate (MN14 (34) and MN16 (36).

If any of the inputs to that NOR gate (38)(V2(50), V3(52), V4(54) or V8 (56) are in a Hi state, the NOR gate (38) output is driven Lo (and the inverter MP7(47)/MN8(48) output goes Hi), thus closing the gate on the sinusoid and isolating it from the output pin (32). This isolation is required in order to hold the output pin in a Hi (MP2 (57) in an ON state), Lo (MN3 (58) in an ON state), or Z (MP2 (60) and MN3 (58) both OFF) state. Voltage source V2 B (50) produces a hold Hi state; V3 (52) produces a hold Lo state and V4 (54) and V8 (56) hold the output in a Z state, respectively. V5 (59), in conjunction with, MP10 (61) and V6 (63), forces the output to a voltage of 1.25V (Vdd/2) to initialize the signal trace to a known value. The RLC networks (62a) (62b) (62c) situated between the transistors and their power supplies model the parasitic losses in the power supply system.

FIG. 4 implements a second embodiment of the same driver circuit. The operation is identical to the circuit disclosed and in FIG. 3 in which V10 and V11 (70) (72) and V12 and V16 (74) (76) and have different size characteristics. The RCL networks use different component sizes as well. FIG. 5 illustrates a transmission line with four evenly spaced loads, one of which is driven by the circuit modeled in FIG. 3 and another by the circuit modeled in FIG. 4, and with termination RLC networks (parasitic effects) at each end (64) (66). To model the worst-case signaling environment, the driver modeled in FIG. 3 is connected to one of the non-end loads.

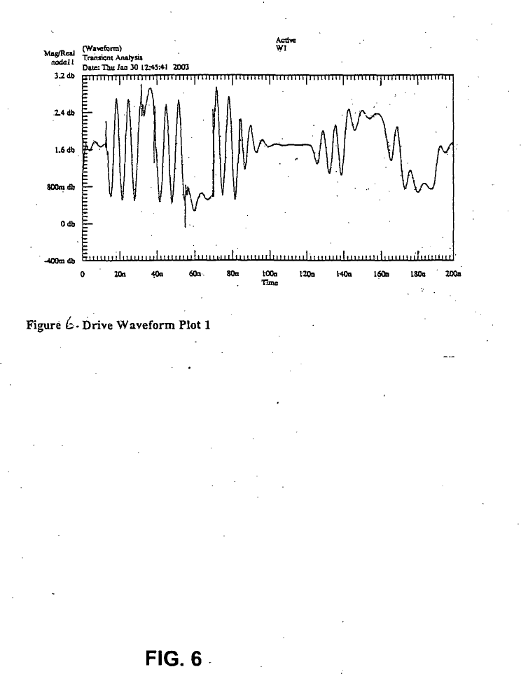

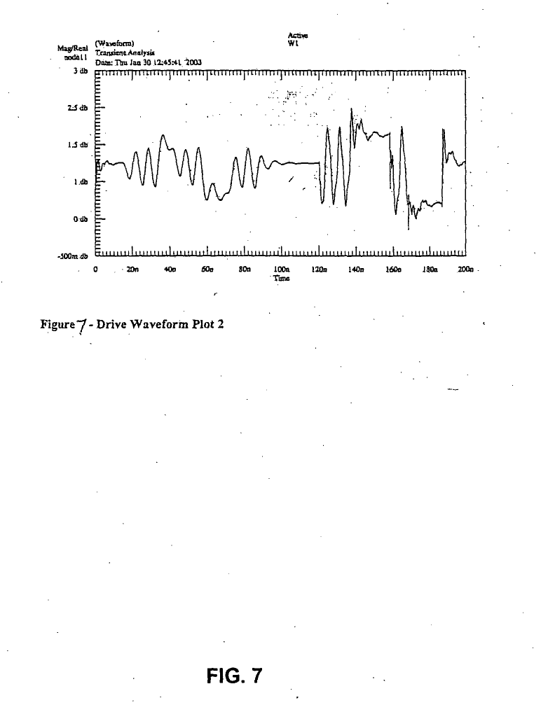

FIGS. 6 and 7 plot the results of simulating the circuit represented in FIGS. 3, 4 and 5. FIG. 6, from OnS to 100nS (82) traces the voltage at the pin driven by the driver in FIG. 3, and FIG. 7 traces that voltage of the receiving pin over the same time period. The direction is reversed in the time period from 1OOn to 200n in both Figures, with the driver in FIG. 4 now active. All edges reaching the receiver are thus clean and monotonic. Such noise as does appear is due, not to reflections or excess harmonic content, but to the extreme simplification of the driver circuit as shown.

The present invention has been described with reference to the above preferred embodiment. The true nature of the present invention is to be determined with reference to the claims attached hereto.

1. A signaling circuit using sinusoidal driven waveforms comprising:
circuit means for driving a pair of sinusoidal waveforms into a driver circuit;
a driver circuit to route either phase of the sinusoid pair to an output pin; and
logic means for selecting between the hold states (Hi, Lo, or Z (neither)) or the sinusoid phase making the required transition during a given transition time.

2. The signaling circuit of claim 1 wherein said driver circuit is integrated with at least one other circuit to form an I/O cell.

3. The signaling circuit of claim 2 wherein said driver circuit is implements a circuit topography from any saturating logic family, including bipolar TTL, CMOS, NMOS, or BiCMOS.

4. A signaling circuit using sinusoidal driven waveforms comprising:
sinusoidal circuit creation means comprising at least one voltage source for driving a pair of offset sinusoidal waveform into a driver circuit;
said driver circuit comprising at least two transistors to hold either a Hi or Lo state and a pair of gated buffers to route either phase of the sinusoid pair to an output pin; and
logic circuit means to select between either a plurality of hold states (Hi, Lo, or Z (neither)) or the sinusoid phase, thereby generating a required transition during a preset transition period.

5. A signaling circuit using sinusoidal driven waveforms of claim 4 wherein the hold states comprise the Hi, Lo or Z states.

6. The signaling circuit of claim 4 wherein said driver circuit is integrated with at least one other circuit to form an I/O cell.

7. The signaling circuit of claim 4 where in said driver circuit is implements a circuit topography from any saturating logic family, including bipolar TTL, CMOS, NMOS, or BiCMOS.

8. A signaling circuit using sinusoidal driven waveforms comprising:
sinusoidal circuit creation means comprising at least one voltage source for driving a pair of offset sinusoidal waveform into a driver circuit;
said driver circuit comprising at least two transistors to hold either a Hi or Lo state and a pair of gated buffers, controlled by a NOR circuit, to route either phase of the sinusoid pair to an isolated output pin; and
logic circuit means to select between either a plurality of hold states or the sinusoid phase, thereby generating a required transition during a preset transition period.

9. A signaling circuit using sinusoidal driven waveforms of claim 8 wherein the hold states comprise the Hi, Lo or Z states.

10. The signaling circuit of claim 8 wherein said driver circuit is integrated with at least one other circuit to form an I/O cell.

11. The signaling circuit of claim 8 where in said driver circuit is implements a circuit topography from any saturating logic family, including bipolar TTL, CMOS, NMOS, or BiCMOS.

12. The signaling circuit of claim 8 further comprising means to eliminate parasitic effects.
